(19) United States
(12) Patent Application Publication
(10) Pub. No.: US 2026/0282322 A1
(43) Pub. Date: Sep. 17, 2026

(54) SEMICONDUCTOR MEMORY DEVICE AND METHOD FOR FORMING THE SAME

(71) Applicant: Winbond Electronics Corp., Taichung City (TW)

(72) Inventor: Frederick CHEN, Tainan City (TW)

(73) Assignee: Winbond Electronics Corp., Taichung City (TW)

(21) Appl. No.: 19/079,855

(22) Filed: Mar. 14, 2025

(51) Int. Cl. H10B 12/00; H10D 30/43; H10D 62/10; H10D 62/40; H10D 62/83

(52) U.S. Cl. CPC H10B 12/31; H10B 12/05; H10B 12/482; H10B 12/485; H10B 12/488; H10B 12/50; H10D 30/43; H10D 62/121; H10D 62/40; H10D 62/83

(57) ABSTRACT

A semiconductor memory device includes memory transistors disposed in respective levels stacked in a first direction, and first conductive lines extending in a second direction. The second direction is perpendicular to the first direction. The first conductive lines are disposed in the respective levels, and are electrically coupled to the first terminals of the memory transistors. The semiconductor memory device further includes second conductive lines extending in the first direction and electrically coupled to the second terminals of the memory transistors, and third conductive lines extending in the first direction and electrically coupled to the third terminals of the memory transistors.

### BACKGROUND

### Field of the Disclosure

The present disclosure relates to a semiconductor memory device, and in particular, it relates to Dynamic Random Access Memory with a three-dimensional structure.

### Description of the Related Art

A DRAM with a three-dimensional structure in which an array of memory cells is stacked in a direction that is perpendicular to the main surface of the substrate becomes a potential way to improve the degree of integration of memory cells.

### SUMMARY

In some embodiments of the disclosure, a semiconductor memory device is provided. The semiconductor memory device includes a plurality of memory transistors over a first substrate and divided into groups. The groups of memory transistors are disposed in respective levels that are stacked in a first direction vertical to a top surface of the first substrate. Each of the memory transistors includes first to fourth terminals. The semiconductor memory device further includes a plurality of first conductive lines extending in a second direction and divided into groups. The second direction is perpendicular to the first direction. The groups of first conductive lines are disposed in the respective levels, and the first conductive lines are electrically coupled to the first terminals of the memory transistors. The semiconductor memory device further includes a plurality of second conductive lines extending in the first direction and electrically coupled to the second terminals of the memory transistors. The semiconductor memory device further includes a plurality of third conductive lines extending in the first direction and electrically coupled to the third terminals of the memory transistors.

In some embodiments of the disclosure, a method for forming a semiconductor memory device is provided. The method includes forming a stack over a first substrate. The stack includes alternating first semiconductor layers and second semiconductor layers. The method further includes removing the first semiconductor layers, forming first conductive lines along first sidewalls of the respective second semiconductor layers, forming a second conductive line adjoining second sidewalls of the second semiconductor layers, forming a third conductive line adjoining third sidewalls of the second semiconductor layers, and forming a fourth conductive line through the second semiconductor layers.

### BRIEF DESCRIPTION OF THE DRAWINGS

In accordance with some embodiments of the present disclosure, it can be further understood by reading the subsequent detailed description and examples with references made to the accompanying drawings, wherein:

FIG. 1 is a circuit diagram schematically illustrating a three-dimensional semiconductor memory device, in accordance with some embodiments.

FIG. 2A is a perspective view illustrating the three-dimensional semiconductor memory device of FIG. 1, in accordance with some embodiments.

FIG. 2B is a plan view illustrating a level of the three-dimensional semiconductor memory device of FIG. 1, in accordance with some embodiments.

FIGS. 3A-1 and 3A-2, FIGS. 3B-1 and 3B-2, FIGS. 3C-1 and 3C-2, FIGS. 3D-1 and 3D-2, FIGS. 3E-1 and 3E-2, FIGS. 3F-1 and 3F-2, FIGS. 3G-1 and 3G-2, FIGS. 3H-1 to 3H-4, FIGS. 3I-1 to 3I-3, and FIG. 3J are schematic diagrams illustrating the formation of a three-dimensional semiconductor memory device at various intermediate stages, in accordance with some embodiments

FIG. 4 is a circuit diagram schematically illustrating a three-dimensional semiconductor memory device, in accordance with some embodiments.

FIG. 5 is a plan view illustrating a level of the three-dimensional semiconductor memory device of FIG. 4, in accordance with some embodiments.

### DETAILED DESCRIPTION

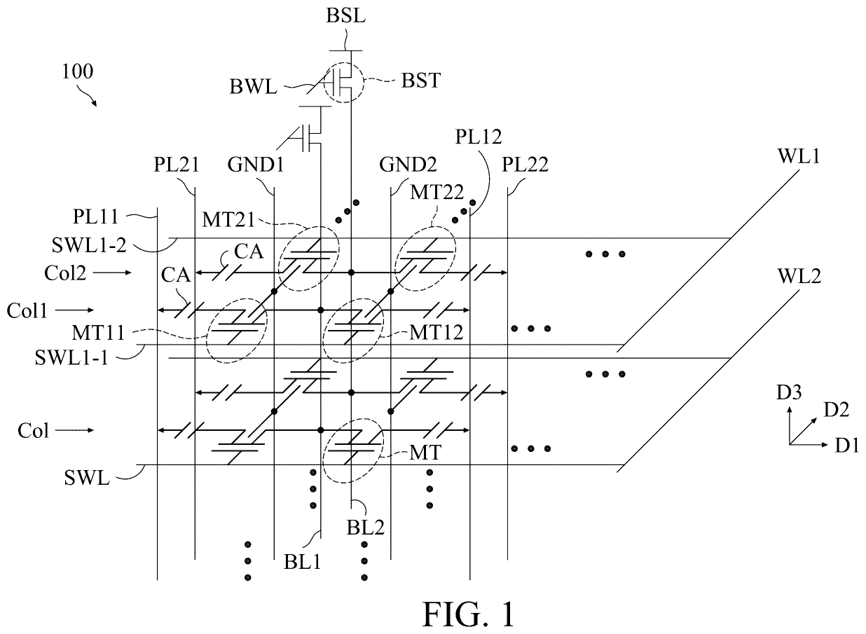

FIG. 1 is a circuit diagram schematically illustrating a three-dimensional semiconductor memory device 100, in accordance with some embodiments. In some embodiments, the semiconductor memory device 100 includes a DRAM device with a three-dimensional structure. In some embodiments, the semiconductor memory device 100 is formed over a substrate. For ease of illustration, FIG. 1 illustrates reference directions, in that the first direction D1 and the second direction D2 are horizontal directions parallel to the top surface of the substrate. The third direction D3 is a vertical direction, and it is perpendicular to the top surface of the substrate. The first direction D1 is substantially perpendicular to the second direction D2.

The semiconductor memory device 100 includes a memory cell array which is a multi-leveled structure and includes a plurality of memory transistors MT. The memory transistors MT are divided into a plurality of groups, and the groups of the memory cells are arranged in the respective levels that are stacked over the substrate in the third direction D3. In each level, the memory transistors MT are arranged into an array along the first direction D1 (column direction) and the second direction D2 (row direction). In the third direction D3, the memory transistors MT in different levels are aligned to each other.

Although two levels are shown in FIG. 1, the embodiments are not limited thereto, for example, the memory cell array may include three, four or more levels, e.g., 5-30. In addition, FIG. 1 shows four memory transistors MT (memory cells) in each level, the embodiments are limited thereto, for example, the number of the memory transistors MT in one level may be dozens, hundreds, or even hundreds of thousands.

The semiconductor memory device 100 further includes a plurality of word lines WL (e.g., WL1 and WL2) and a plurality of sub-word lines SWL. The word lines WL are longitudinally oriented along the second direction D2, and the sub-word lines SWL are longitudinally oriented along the first direction D1. Each of the word lines WL and a set of sub-word lines SWL electrically connected to thereto are disposed in a corresponding level, and may be collectively referred to as a joined horizontal word line. For example, the word line WL1 and the sub-word lines SWL1-1 and SWL1-2 which are electrically connected to the word line WL1 are disposed in the top level, as shown in FIG. 1. As a result, the word lines WL are decoded and selected along the third direction D3, which may save the area of the substrate for picking up word lines.

In each level, the gate terminals of all memory transistors MT in the corresponding group are electrically coupled to the same word line WL through the sub-word lines SWL. For example, the gate terminals of the memory transistors MT11 and MT12 are electrically coupled to the sub-word line SWL1-1; the gate terminals of the memory transistors MT21 and MT22 are electrically coupled to the sub-word line SWL1-2; and both the sub-word lines SWL1-2 and SWL1-2 are electrically connected to the word line WL1.

In each level, the memory transistors MT in the corresponding group are arranged into a plurality of columns Col extending in the first direction D1. Two adjacent columns Col (e.g., Col1 and Col2) of memory transistors MT are disposed between two adjacent sub-word lines SWL (e.g., SWL1-1 and SWL1-2).

The terminals of the memory transistors MT in one column Col and the terminals of the memory transistors MT in an adjacent column Col are arranged in opposite manner. For example, the body terminals of the memory transistors MT11 and MT12 in the column Col1 and the body terminals of the memory transistors MT21 and MT22 in the column Col2 face inwards and face each other. The gate terminals of the memory transistors MT11 and MT12 in the column Col1 and the gate terminals of the memory transistors MT21 and MT22 in the column Col2 face outwards and face away from each other.

The semiconductor memory device 100 further includes a plurality of bit lines BL (e.g., BL1 and BL2). The bit lines BL are longitudinally oriented along the third direction D3. In each level, the source terminals of two adjacent memory transistors MT which are arranged in the first direction D1 are electrically coupled to one common bit line BL. For example, the source terminals of the memory transistors MT11 and MT12 are electrically coupled to the bit line BL1, and the source terminals of the memory transistors MT21 and MT22 are electrically coupled to the bit line BL2.

The semiconductor memory device 100 further includes a plurality of ground lines GND (e.g., GND1 and GND2). The ground lines GND are longitudinally oriented along the third direction D3. In each level, the body terminals of two adjacent memory transistors MT which are arranged in the second direction D2 are electrically coupled to one common ground line GND. For example, the body terminals of the memory transistors MT11 and MT21 are electrically coupled to the ground line GND1, and the body terminals of the memory transistors MT12 and MT22 are electrically coupled to ground line GND2. The ground lines GND may apply a reference voltage to the body terminals of the memory transistors MT, and the performance variation between different memory transistors may be thus reduced, e.g., the difference of threshold voltage.

The semiconductor memory device 100 further includes a plurality of capacitors CA and a plurality of plate lines PL (e.g., PL11, PL12, PL21 and PL22). Each of the capacitors CA is coupled to a memory transistor MT, with its first electrode electrically connected to the drain terminal of the corresponding memory transistor MT. The plate lines PL are longitudinally oriented along the third direction D3 and may serve as second electrodes of the capacitors CA.

The semiconductor memory device 100 further includes a plurality of bit line select transistors BST above the memory cell array, a plurality of bit line select word lines BWL, and a plurality of bit line select source lines BSL which are disposed above the memory cell array. Each bit line select transistor BST has a gate terminal which is electrically connected to a corresponding bit line select word line BWL. Each bit line select transistor BST has a drain terminal which is electrically connected to a corresponding bit line BL. Each bit line select transistor BST has a source terminal which is electrically connected to a corresponding bit line select source line BSL. The select transistor BST is used to decode the bit lines BL along the first direction D1 and the second direction D2. The select transistor BST are used to decode and select the bit lines BL along the first direction D1 and the second direction D2 respectively. Specifically, the select source lines BSL and the select word lines BWL are used to decode along the second direction D2 and the first direction D1, respectively.

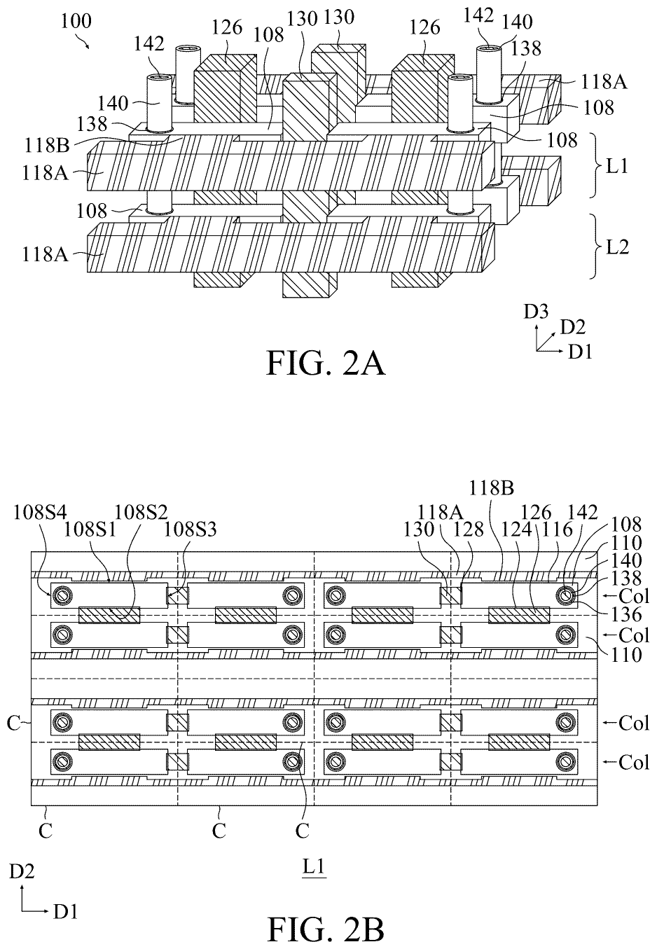

FIG. 2A is a perspective view illustrating a three-dimensional semiconductor memory device 100 of FIG. 1, in accordance with some embodiments. FIG. 2B is a plan view illustrating a level L1 of the three-dimensional semiconductor memory device 100, in accordance with some embodiments. Features of the semiconductor memory device 100 may be described below using the level L1, but these features can be suitable for other levels.

The semiconductor memory device 100 includes a plurality of nanowires 108, a plurality of first conductive lines 118A, a plurality of second conductive lines 126, a plurality of third conductive lines 130, electrodes 138, capacitor dielectric layers 140 and a plurality of fourth conductive lines 142. For clarity, some components of the semiconductor memory device 100 are not shown in FIG. 2A, but may be seen in FIG. 2B and subsequent figures. In addition, although nanowires are illustrated in the figures, the memory transistor may include any applicable nanostructures, e.g., nanosheets, nanotubes, etc.

The semiconductor memory device 100 is a multi-leveled structure in which levels L1 and L2 are vertically stacked in the Z direction, as shown in FIG. 2A. Although two levels are shown, the embodiments are limited thereto, for example, the multi-leveled structure may include three, four or more levels, e.g., 5-30. The semiconductor memory device 100 may include or be defined as a plurality of memory cells C which are arranged along the first direction D1 and the second direction D2 and stacked in the third direction D3 to form a 3D memory cell array.

The nanowires 108 extend in the first direction D1 and are formed in the respective memory cells C. The nanowires 108 function as active regions. Each of the nanowires 108 has first and second sides 108S1 and 108S2 extending in the first direction D1 and third and fourth sides 108S3 and 108S4 extending in the second direction D2, as shown in FIG. 2B. The first conductive lines 118A are formed along the first sides 108S1 of the nanowires 108, the second conductive lines 126 are adjoined to the second sides 108S2 of the nanowires 108, and the third conductive lines 130 are adjoined to the third sides 108S3 of the nanowires 108.

The first conductive lines 118A extend in the first direction D1 and include protruding portion 118B extending toward the first sidewalls 108S1 of the nanowires 108. The first conductive lines 118A are configured as the sub-word lines SWL of FIG. 1. The protruding portions 118B are disposed in the respective memory cells C and may be used as gate electrodes. The protruding portions 118B combine with gate dielectric layer 116 between the protruding portion 118B and the nanowires 108 to form gate structures. Each of the gate structures engages the channel region of the corresponding nanowire 108 to form a memory transistor (e.g., MT of FIG. 1) in a memory cell C. In each of the levels L1 and L2, the nanowires 108 are arranged into a plurality of columns Col extending in the first direction D1. Two adjacent columns Col of nanowires 108 are disposed between two first conductive lines 118A.

The second conductive lines 126 extend in the third direction D3 and penetrate through the levels L1 and L2. The second conductive lines 126 are configured as the ground lines GND of FIG. 1. In each of the levels L1 and L2, one second conductive line 126 is electrically connected to the body regions of the two nanowires 108 arranged in the second direction D2 at their second sidewalls 108S2. Contact regions 124 are formed between the nanowires 108 and the second conductive lines 126. The nanowires 108 may be electrically grounded through the second conductive lines 126.

The third conductive lines 130 extend in the third direction D3 and penetrate through the levels L1 and L2. The third conductive lines 130 are configured as the bit lines BL of FIG. 1. In each of the levels L1 and L2, one third conductive line 130 is electrically connected to the source regions of the two nanowires 108 arranged in the first direction D1 at their third sidewalls 108S3. Contact regions 128 are formed between the nanowires 108 and the third conductive lines 130.

The electrodes 138 are formed in the drain regions of the nanowires 108, and the capacitor dielectric layers 140 and the fourth conductive lines 142 extend in the third direction D3 and penetrate through the drain regions of the nanowires 108. In each of the levels L1 and L2, the fourth conductive lines 142 are wrapped by the respective capacitor dielectric layers 140, and the capacitor dielectric layers 140 are wrapped by the respective electrodes 138. In each memory cell C, a set of the electrodes 138, the capacitor dielectric layers 140 and the portions of the fourth conductive lines 142 in the nanowires 108 serve a capacitor CA of FIG. 1. Contact regions 136 are formed between the nanowires 108 and the third electrodes 138.

The semiconductor memory device 100 further includes an isolation structure 110 which fills the remaining space of the semiconductor memory device 100 to encapsulate nanowires 108 and the conductive lines 118A, 126 and 130 and the capacitor dielectric layers 140.

The method for forming the semiconductor memory device 100 is discussed below. FIGS. 3A-1 through 3I-1 are plan views illustrating the formation of the semiconductor memory device 100 at various intermediate stages. The plan views cut through one of the second semiconductor layers 108 of the semiconductor memory device 100 (i.e., one level of the memory cell array). For simplicity and clarity, the plan views only show one memory cell to illustrate the formation of the semiconductor memory device 100.

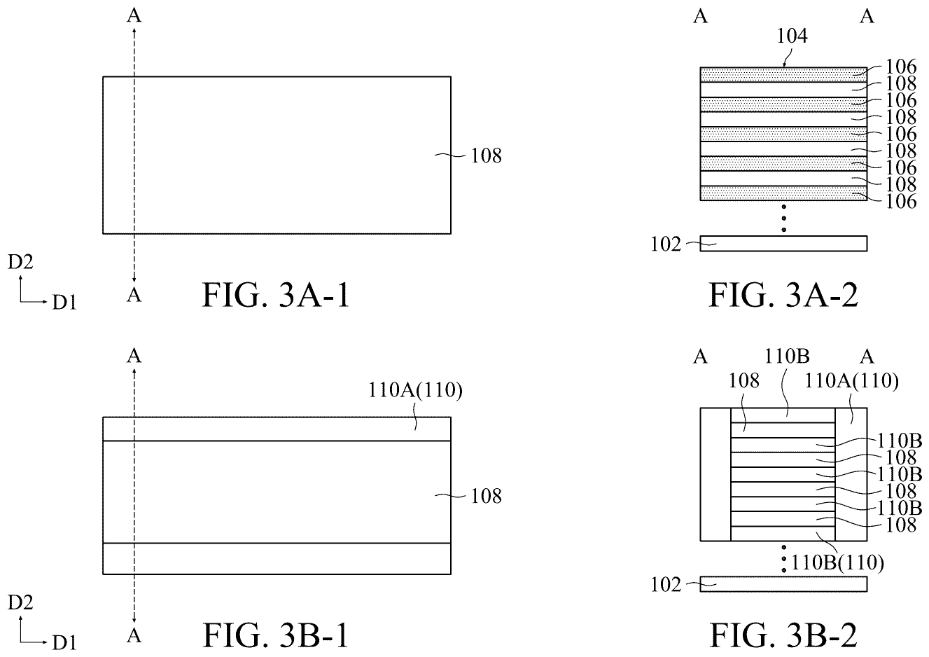

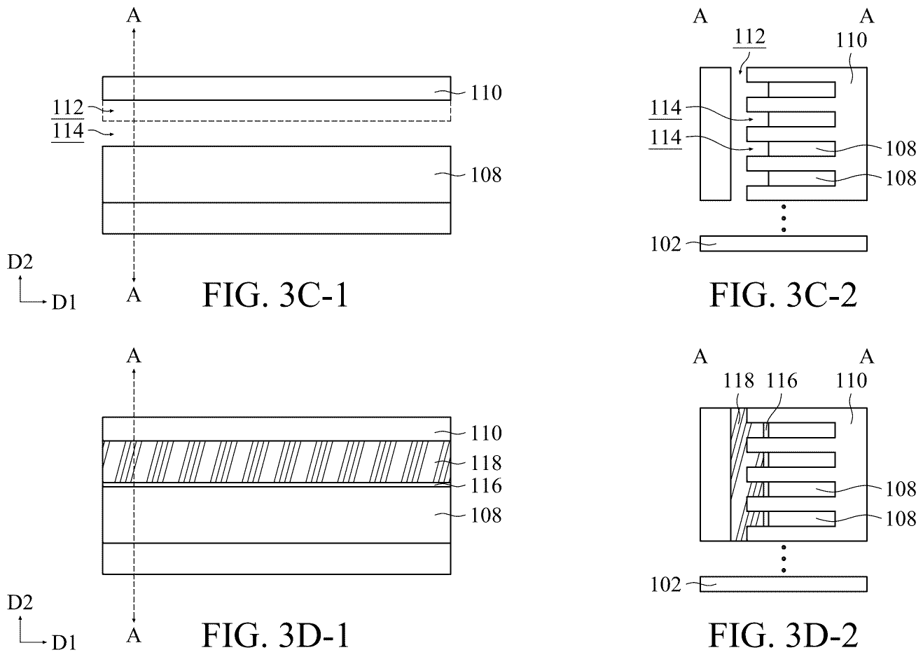

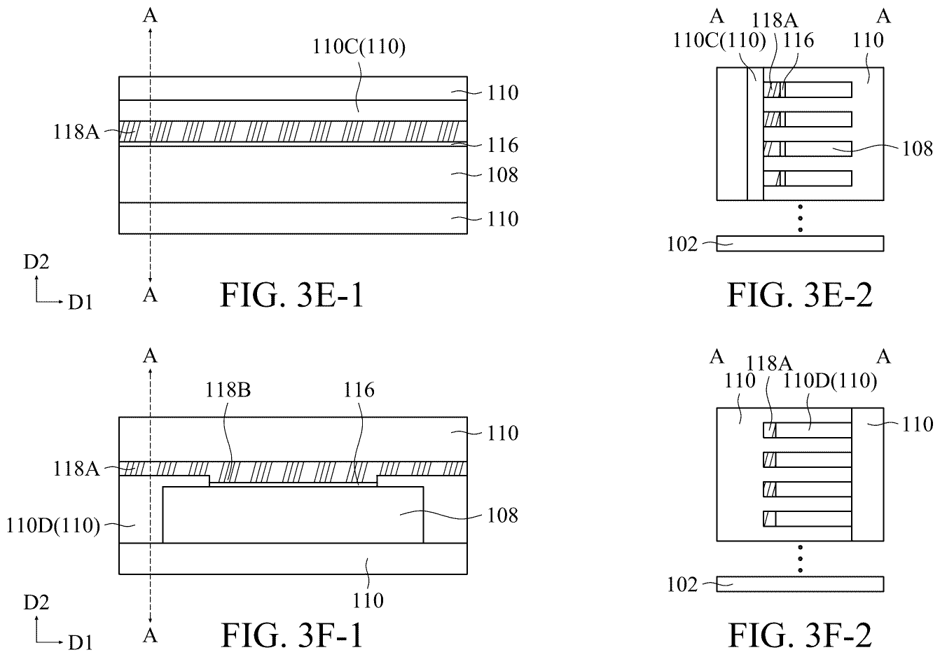

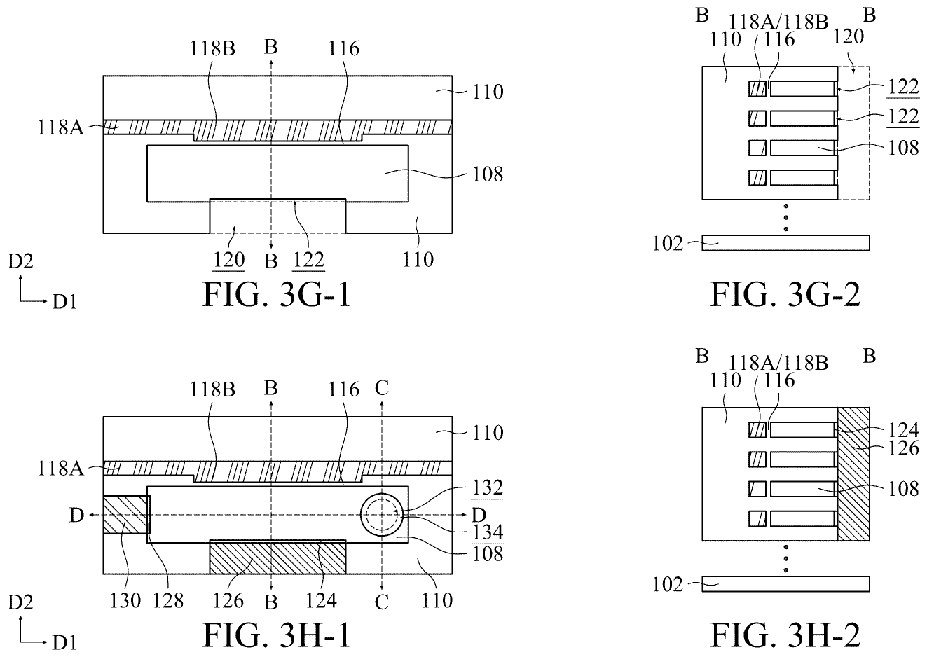

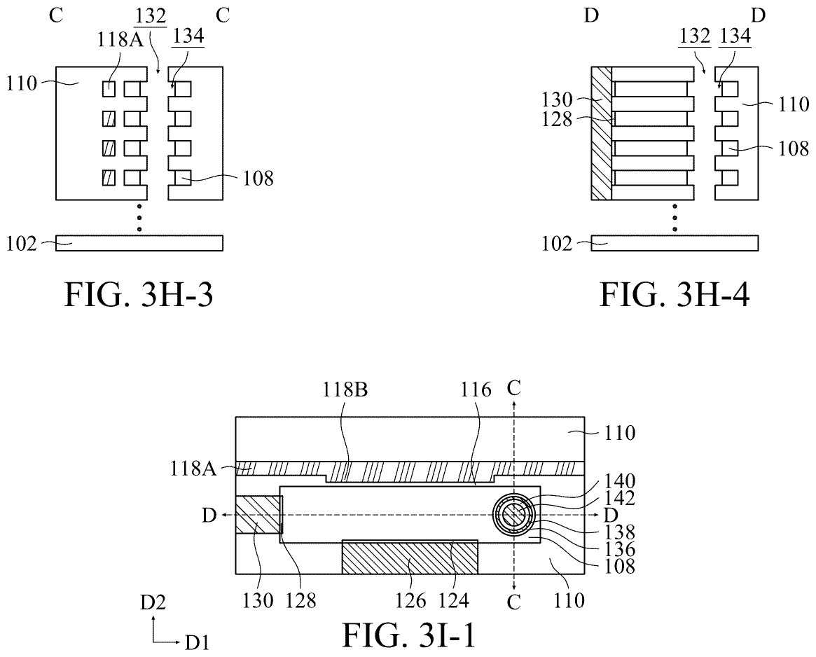

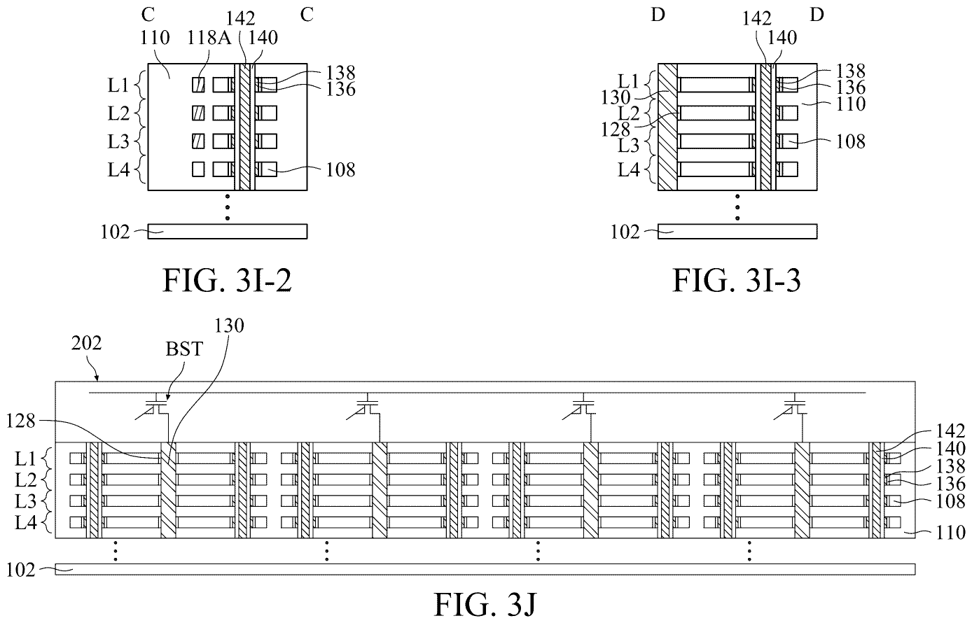

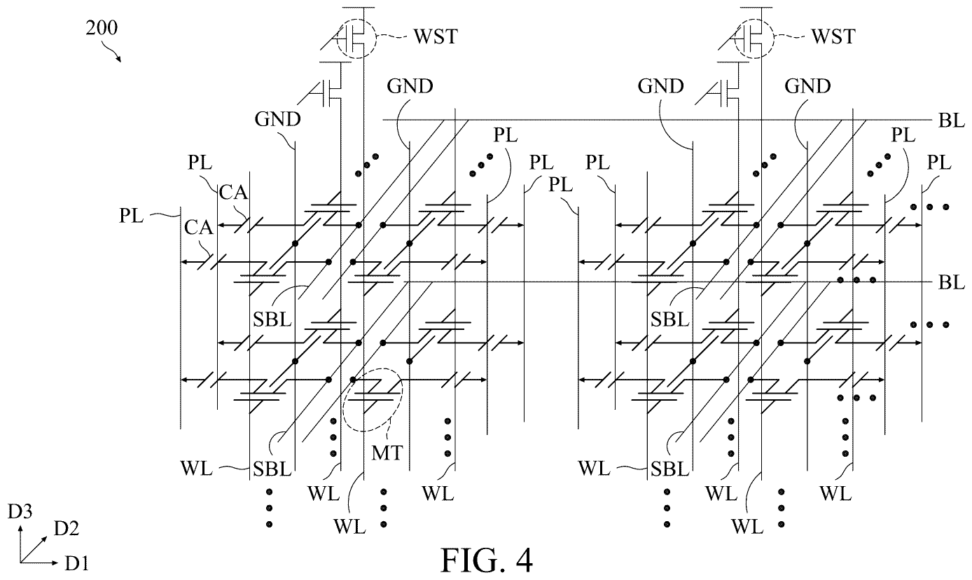

FIGS. 3A-2, 3B-2, 3C-2, 3D-2, 3E-2 and 3F-2 are cross-sectional view corresponding to line A-A of FIGS. 3A-1, 3B-1, 3C-1, 3D-1, 3E-1 and 3F-1. FIGS. 3G-2 and 3H-2 are cross-sectional views corresponding to line B-B of FIGS. 3G-1 and 3H-1. FIGS. 3H-3 and 3I-2 are cross-sectional views corresponding to line C-C of FIGS. 3H-1 and 3I-1. FIGS. 3H-4 and 3I-3 are cross-sectional views corresponding to line D-D of FIGS. 3H-1 and 3I-1.

A stack 104 is formed on the first substrate 102, as shown in FIGS. 3A-1 and 3A-2 The first substrate 102 may be or includes a semiconductor substrate (e.g., Si substrate). The stack 104 includes alternating first semiconductor layers 106 and second semiconductor layers 108. In some embodiments, the first semiconductor layers 106 may be made of SiGe, and the second semiconductor layers 108 may be made of Si. The first semiconductor layers 106 are sacrificial layer and will be replace by the isolation structure 110, and the second semiconductor layers 108 are used as active regions. In some embodiments, the first semiconductor layers 106 and the second semiconductor layers 108 are grown from the top surface of the first substrate 102 using an epitaxial growth process. Each of the semiconductor layers 106 and 108 may be a single crystal epitaxial layer.

The stack 104 is patterned using photobiography and etching processes to form trenches and a strip protruding from between the trenches, as shown in FIGS. 3B-1 and 3B-2. The strip extends in the first direction D1. An insulating material 110A is then formed in the trenches using a deposition process followed by an etching process or a chemical mechanical polishing process. The insulating material 110A may be made of dielectric material such as silicon oxide (SiO), silicon nitride (SiN), silicon oxynitride (SiON), another suitable dielectric material, or a combination thereof. The insulating material 110A is a portion of the resulting isolation structure 110, and denoted as 110 in the subsequent figures.

Afterwards, the first semiconductor layers 106 are removed using an etching process to form gaps, and an insulating material 110B are formed in the gaps using deposition and etching-back processes. The insulating material 110B may be made of dielectric material such as silicon oxide (SiO), silicon nitride (SiN), silicon oxynitride (SiON), another suitable dielectric material, or a combination thereof. The insulating material 110B is a portion of the resulting isolation structure 110, and denoted as 110 in the subsequent figures.

The insulating material 110B and the second semiconductor layers 108 are etched to form a through trench 112 vertically penetrating through the isolation structure 110 and the second semiconductor layers 108, as shown in FIGS. 3C-1 and 3C-2. The through trench 112 extends in the first direction D1. The second semiconductor layers 108 are then laterally recessed from the through trench 112 using an etching process to form notches 114.

Gate dielectric layers 116 are formed on the exposed sidewall (e.g., 108S1 in FIG. 2B) of the second semiconductor layers 108 in the notches 114 using a deposition process followed by an etching process, as shown in FIGS. 3D-1 and 3D-2. In some embodiments, the gate dielectric layer 116 is made of silicon oxide (SiO), silicon nitride (SiN), silicon oxynitride (SiON), another suitable dielectric material, or a combination thereof.

A conductive layer 118 is then formed to fill the through trench 112 and the notches 114 using a deposition process followed by an etching process or a chemical mechanical polishing process. In some embodiments, the conductive layer 118 is made of metal material (such as W, Al, Cu, Co, or Ru), or metal nitride (such as TiN or TaN), or a combination thereof.

The portion of the conductive layer 118 in the through trench 112 is removed using an etching process to form the through trench again, and an insulating material 110C is then formed in the through trench using a deposition process followed by an etching process or a chemical mechanical polishing process, as shown in FIGS. 3E-1 and 3E-2. The insulating material 110C may be made of dielectric material such as silicon oxide (SiO), silicon nitride (SiN), silicon oxynitride (SiON), another suitable dielectric material, or a combination thereof. The insulating material 110C is a portion of the resulting isolation structure 110, and denoted as 110 in the subsequent figures. The portions of the first conductive layer 118 in the notches 114 form first conductive lines 118A.

One or more etching process is performed to laterally recess the nanowires 108, the gate dielectric layer 116 and the first conductive lines 118A to form notches, and an insulating material 110D is then formed in the notches using a deposition process followed by an etching process or a chemical mechanical polishing process, as shown in FIGS. 3F-1 and 3F-2. The insulating material 110D may be made of dielectric material such as silicon oxide (SiO), silicon nitride (SiN), silicon oxynitride (SiON), another suitable dielectric material, or a combination thereof. The insulating material 110D is a portion of the resulting isolation structure 110, and denoted as 110 in the subsequent figures.

As a result, the strip is patterned into an island which is surrounded by the isolation structure 110. The second semiconductor layers 108 in the island serve as nanowires 108. In addition, the first conductive lines 118A include protruding portions 118B adjoining the channel regions of the nanowires 108 at the first sidewalls (108S1 in FIG. 2B).

The isolation structure 110 is etched using an etching process to form a through hole 120 vertically penetrating through the isolation structure 110 and the nanowires 108, as shown in FIGS. 3G-1 and 3G-2. The second sidewalls (e.g., 108S2 in FIG. 2B) of the nanowires 108 are exposed from the through hole 120. The nanowires 108 are laterally recessed from the through hole 120 using an etching process to form notches 122. Although no interface between the gate dielectric layer 116 and the isolation structure 110 is shown, that there may be a physical interface between the gate dielectric layer 116 and the isolation structure 110 in some other embodiments.

Contact region 124 is formed on the exposed sidewall (e.g., 108S2 in FIG. 2B) of the nanowires 108 in the notches 122 using a deposition process followed by an etching process, as shown in FIGS. 3H-1 and 3H-2. The contact regions 124 may be made of doped semiconductor material (such as polysilicon) with n-type or p-type dopants. A second conductive line 124 is formed in the through hole 120 using a deposition process followed by an etching process or a chemical mechanical polishing process. In some embodiments, the second conductive line 124 is made of metal material (such as W, Al, Cu, Co, or Ru), or metal nitride (such as TiN or TaN), or a combination thereof.

Contact regions 128 are formed on the third sidewalls (e.g., 108S3 in FIG. 2B) of the nanowires 108, and a third conductive line 130 is formed through the isolation structure 110 and on the contact regions 128, as show in FIGS. 3H-1 and 3H-4. The formation and the material of the contact regions 128 and the third conductive line 130 may be similar to the formation and the material of the contact regions 124 and the second conductive line 126.

The nanowires 108 and the isolation structure 110 are etched using an etching process to form a through hole 132, and the nanowires 108 are laterally recessed from the through hole 132 using an etching process to form notches 134, as shown in FIGS. 3H-1, 3 H-3 and 3H-4.

Contact regions 136 are formed on the exposed surfaces of the nanowires 108 in the notches 134 using a deposition process followed by an etching process, as shown in FIGS. 3I-1, 3I-2 and 3I-3. The contact regions 136 may be made of doped semiconductor material (such as polysilicon) with n-type or p-type dopants. Electrodes 138 are formed on the contact regions 136 in the notches 134 using a deposition process followed by an etching process. The electrodes 138 is made of metal material (such as W, Al, Cu, Co, or Ru), or metal nitride (such as TiN or TaN), or a combination thereof.

A capacitor dielectric layer 140 and a fourth conductive line 142 are sequentially formed in the through hole 132 using deposition processes followed by an etching process or a chemical mechanical polishing process. The capacitor dielectric layer 140 is made of silicon oxide, hafnium oxide, zirconium oxide, hafnium zirconium oxide, hafnium silicon oxide, aluminum oxide, lanthanum oxide, tantalum oxide, titanium oxide, another suitable dielectric material, and/or a combination thereof. The fourth conductive line 142 is made of metal material (such as W, Al, Cu, Co, or Ru), or metal nitride (such as TiN or TaN), or a combination thereof. As shown in FIG. 3I-1, the contact region 136, the electrodes 138, the capacitor dielectric layer 140 and the fourth conductive line 142 have respective ring-shape profiles, and may be concentric. After the fourth conductive line 142 is formed, the memory cell array with multiple levels (e.g., L1-L4) is obtained.

Next, a second substrate 202 is disposed on the first substrate 102 using a bonding process, as shown in FIG. 3J. The second substrate 202 may be or includes a semiconductor substrate (e.g., Si substrate). The second substrate 202 includes a device layer in which a plurality of bit line select transistors BST are pre-formed on the second substrate 202 before the bonding process.

Each of the bit line select transistors BST on the second substrate 202 corresponds to and is electrically coupled to one third conductive lines 130 on the first substrate 102. The second substrate 202 may further include other applicable devices such as periphery circuits, decoders, drivers, sense amplifiers, or a combination thereof, which are electrically connected to the memory cell array formed on the first substrate 102. In some embodiments, the bit line select transistors BST and the other applicable devices are manufactured using a conventional CMOS process. Disposing these CMOS devices (e.g., the bit line select transistors BST and the other applicable devices described above) above the memory cell array the first substrate 102 may improve the utilization of the substrate area.

In addition, because the CMOS devices are manufactured on the second substrate 202, the thermal budget of the manufacturing the memory cell array on the first substrate 102 may not be negatively affected. Therefore, the performance, reliability and/or yield of manufacturing the semiconductor memory device may be improved.

Furthermore, compared with CUA (CMOS under array) architecture where the CMOS devices are formed under the memory cell array, the embodiments of the present disclosure form the memory cell array directly from the top surface of the first substrate 102, which may allow the single crystal silicon nanowires 108 for the channel layers. Compared with the poly-crystal silicon channel layers, the single-crystal channel layers may reduce noise during the operation of the resulting semiconductor memory device.

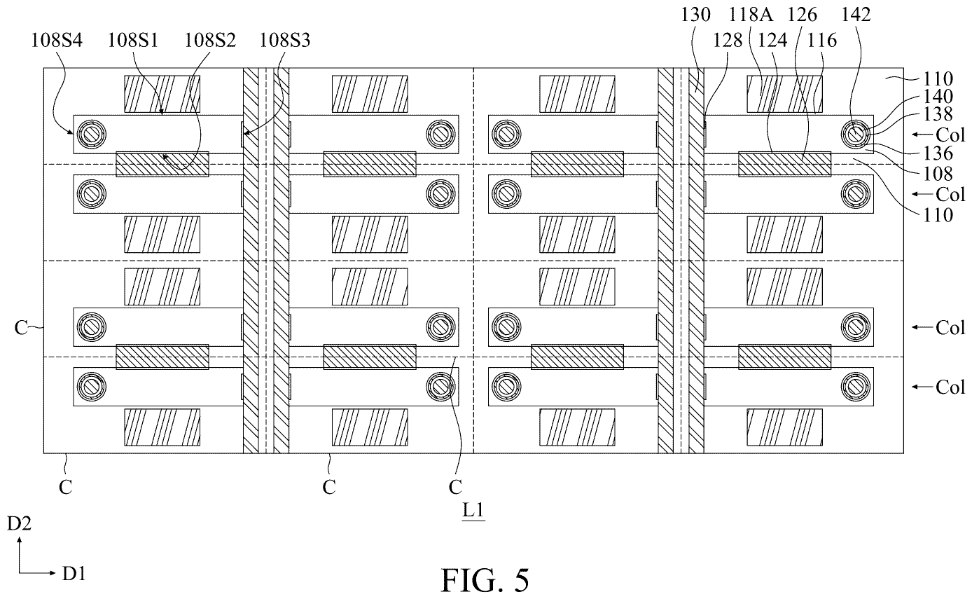

FIG. 4 is a circuit diagram schematically illustrating a three-dimensional semiconductor memory device 200, in accordance with some embodiments. FIG. 5 is a plan view illustrating a level of the three-dimensional semiconductor memory device 200, in accordance with some embodiments. The semiconductor memory device 200 of FIGS. 4 and 5 is similar to the semiconductor memory device 100 of FIGS. 1 to 3J except that word lines WL extend vertically and bit lines BL extend horizontally.

Referring to FIG. 4, the word lines WL are longitudinally oriented along the third direction D3, and the bit lines BL are longitudinally oriented along the first direction D1. In each level, the gate terminals of the memory transistors MT are electrically coupled to the word lines WL. The semiconductor memory device 200 further includes a plurality of sub-bit lines SBL longitudinally oriented along the second direction D2. Each of the bit lines BL and a set of sub-bit lines SBL electrically connected to thereto are disposed in the corresponding level, and may be referred to as a joined horizontal bit line. The bit lines BL are decoded and selected along the third direction D3. The semiconductor memory device 200 further includes word line select transistors WST above the memory cell array. The select transistors WST are used to decode the word lines WL along the first direction D1 and the second direction D2. The select source lines and select word lines of the word line select transistors WST are used to decode along the second direction D2 and the first direction D1respectively.

Referring to FIG. 5, the first conductive lines 118A extend in the third direction D3 and are configured as the word lines WL of FIG. 4, and the third conductive lines 130 extend in the second direction D2. The third conductive lines 130 are configured as the sub-bit lines SBL of FIG. 4. In each level, the nanowires 108 are arranged into a plurality of rows extending in the second direction D2. The third conductive lines 130 are more easily disposed in pairs between two adjacent rows of nanowires 108. Unlike the semiconductor memory device 100 in FIG. 2, the third conductive lines 130 of the semiconductor memory device 200 are strips that extend lengthwise along the second direction D2 across a plurality of memory cells C in the plan view (or in a level), as shown in FIG. 5. The configuration of the other components of the semiconductor memory device 200 is basically as described above with respect to FIGS. 2A and 2B and will not be repeated.

In addition, the formation of the semiconductor memory device 200 may be similar to the formation of the semiconductor memory device 100. For example, the formation of the third conductive lines 130 may include etching the isolation structure 110 and the second semiconductor layers 108 to form a through trench, laterally recessing the isolation structure 110 and the second semiconductor layers 108 from the through trench to form notches, forming the contact regions 128 on the second semiconductor layers 108 in the notches, forming the third conductive lines 130 in the notches, and forming an insulating material in the through trench. The formation of the first conductive lines 118A may include etching the isolation structure 110 to form a through hole, forming the gate dielectric layers 116 on the sidewalls of the second semiconductor layers 108, and forming the first conductive lines 118A in the through hole.

As described above, the embodiments of the present disclosure provide an architecture for a three-dimensional DRAM device and the method for forming the same. In accordance with the embodiments, the memory cell array including the second semiconductor layers 108 are formed from the top surface of the first substrate 102, and CMOS devices such as the bit line select transistors are formed on the second substrate 202 which is disposed above the memory cell array of the first substrate 102. As a result, the utilization of the substrate area may be improved, the thermal budget of manufacturing the memory cell array may not be negatively affected, and the silicon nanowires with a single crystal structure may be realized. Therefore, the performance, reliability and/or yield of manufacturing the semiconductor memory device may be improved.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor memory device, comprising:
a plurality of memory transistors over a first substrate and divided into groups, wherein the groups of memory transistors are disposed in respective levels that are stacked in a first direction vertical to a top surface of the first substrate, and each of the memory transistors includes first to fourth terminals;
a plurality of first conductive lines extending in a second direction perpendicular to the first direction and divided into groups, wherein the groups of first conductive lines are disposed in the respective levels, and the first conductive lines are electrically coupled to the first terminals of the memory transistors;
a plurality of second conductive lines extending in the first direction and electrically coupled to the second terminals of the memory transistors; and
a plurality of third conductive lines extending in the first direction and electrically coupled to the third terminals of the memory transistors.

2. The semiconductor memory device as claimed in claim 1, wherein the first terminal is a gate terminal, the second terminal is a source terminal, and the third terminal is a body terminal.

3. The semiconductor memory device as claimed in claim 1, wherein the first terminal is a source terminal, the second terminal is a gate terminal, and the third terminal is a body terminal.

4. The semiconductor memory device as claimed in claim 1, wherein in each of the levels, the first conductive lines in the corresponding group are sub-word lines, and the first conductive lines electrically connect to a word line that extends in a third direction perpendicular to the first direction and the second direction.

5. The semiconductor memory device as claimed in claim 1, wherein each of the memory transistors includes an active region which is made of single crystal silicon.

6. The semiconductor memory device as claimed in claim 5, wherein each of the third conductive lines is disposed between and electrically coupled to two adjacent active regions that are arranged in a third direction, wherein the third direction is perpendicular to the first direction and the second direction.

7. The semiconductor memory device as claimed in claim 5, wherein in each of the levels, each of the second conductive lines is disposed between and electrically coupled to two adjacent active regions that are arranged in the second direction.

8. The semiconductor memory device as claimed in claim 5, further comprising:
a plurality of fourth conductive lines extending in the first direction, wherein in each of the levels, each of the fourth conductive lines includes a portion disposed within a corresponding active region.

9. The semiconductor memory device as claimed in claim 8, further comprising:
a plurality of capacitors electrically coupled to the fourth terminals of the respective memory transistors, wherein each of the capacitors includes a first electrode, a capacitor dielectric layer within the first electrode, and a second electrode within the capacitor dielectric layer, and the second electrode of each of the capacitors includes the portion of the corresponding fourth conductive line.

10. The semiconductor memory device as claimed in claim 1, wherein in each of the levels, the memory transistors in the corresponding group are divided into columns, and two adjacent columns are disposed between two adjacent first conductive lines.

11. The semiconductor memory device as claimed in claim 1, further comprising:
a second substrate stacked above the first substrate and including a plurality of select transistors, wherein the select transistors are electrically coupled to the respective second conductive lines.

12. The semiconductor memory device as claimed in claim 1, wherein each of the memory transistors includes a nanowire, and each of the first conductive lines includes protruding portions extending toward the sidewalls of the nanowires.

13. The semiconductor memory device as claimed in claim 1, wherein:
in each of the levels, the first conductive lines in the corresponding group are sub-bit lines which electrically connect to a bit line, and
in each of the levels, the memory transistors in the corresponding group are divided into rows, and two adjacent first conductive lines are disposed between two adjacent rows.

14. A method for forming a semiconductor memory device, comprising:
forming a stack over a first substrate, wherein the stack includes alternating first semiconductor layers and second semiconductor layers;
removing the first semiconductor layers;
forming first conductive lines along first sidewalls of the respective second semiconductor layers;
forming a second conductive line adjoining second sidewalls of the second semiconductor layers;
forming a third conductive line adjoining third sidewalls of the second semiconductor layers; and
forming a fourth conductive line through the second semiconductor layers.

15. The method for forming the semiconductor memory device as claimed in claim 14, wherein the first conductive lines are longitudinally oriented along a horizonal direction, and the second conductive line is longitudinally oriented along a vertical direction.

16. The method for forming the semiconductor memory device as claimed in claim 14, further comprising:
forming an insulating material in gaps between the second semiconductor layers;
etching the insulating material and the second semiconductor layers to form a through trench;
laterally etching the second semiconductor layers to form notches;
forming a conductive layer in the notches and the through trench; and
removing a portion of the conductive layer in the through trench, thereby forming the first conductive lines in the notches.

17. The method for forming the semiconductor memory device as claimed in claim 16, further comprising:
forming gate dielectric layers in the notches before forming the conductive layer.

18. The method for forming the semiconductor memory device as claimed in claim 14, further comprising:
forming an isolation structure to surround the stack; and
etching the isolation structure to form a first through hole exposing the second sidewalls of the second semiconductor layers, wherein the second conductive line is formed in the first through hole.

19. The method for forming the semiconductor memory device as claimed in claim 18, further comprising:
etching the isolation structure to form a second through hole exposing the third sidewalls of the second semiconductor layers, wherein the third conductive line is formed in the second through hole.

20. The method for forming the semiconductor memory device as claimed in claim 19, further comprising:
forming first contact regions between the second conductive line and the second semiconductor layers, wherein the first contact regions are made of a semiconductor material; and
forming second contact regions between the third conductive line and the second semiconductor layers, wherein the second contact regions are made of a semiconductor material.
